(19) United States
(12) Patent Application Publication
(10) Pub. No.: US 2025/0374758 A1
(43) Pub. Date: Dec. 4, 2025

(54) DISPLAY PANEL AND DISPLAY DEVICE INCLUDING THE SAME

(71) Applicant: LG Display Co., Ltd., Seoul (KR)

(72) Inventors: Guen Sik LEE, Paju-si (KR); Seung Taek OH, Paju-si (KR); Yong Woo YUN, Paju-si (KR)

(73) Assignee: LG Display Co., Ltd., Seoul (KR)

(21) Appl. No.: 19/221,197

(22) Filed: May 28, 2025

(30) Foreign Application Priority Data
May 30, 2024 (KR) 10-2024-0070899

(51) Int. Cl. H10K 59/121; G09G 3/3233; H10K 59/35

(52) U.S. Cl. CPC H10K 59/121; G09G 3/3233; H10K 59/353; G09G 2300/0819; G09G 2300/0842; G09G 2300/0861; G09G 2320/0233; G09G 2320/0686; G09G 2330/021

(57) ABSTRACT

A display panel and a display device including the same are discussed. The display panel in some example includes a first region including a plurality of pixels having a first pixel density, a second region including a plurality of pixels having a second pixel density lower than the first pixel density, a boundary region including a plurality of pixels having a third pixel density higher than the second pixel density and equal to the first pixel density, and including a plurality of unit emission regions in which a maximum value among luminance values of respective pixels gradually changes, and a transition region including a plurality of pixels having a fourth pixel density higher than the second pixel density and lower than the third pixel density. A boundary between the boundary region and the transition region includes an inflection point where a luminance gradient of pixels changes.

### CROSS-REFERENCE TO RELATED APPLICATION

This application claims priority to Korean Patent Application No. 10-2024-0070899, filed in the Republic of Korea on May 30, 2024, the entire contents of which are hereby expressly incorporated by reference into the present application.

### BACKGROUND

### Technical Field

The present disclosure relates to a display panel, and more specifically, for example, without limitation, to a display panel in which a degree of reduction or the amount of reduction of the element lifespan and the range of available data voltages can be reduced, and to a display device including the same.

### Discussion of the Related Art

Electroluminescence display devices can be classified into inorganic light-emitting display devices and organic light-emitting displays according to a material of an emission layer. An active matrix organic light-emitting display device includes an organic light-emitting diode (OLED) that generates light by itself and has advantages in terms of a high response rate, high luminous efficiency, high luminance, and a large viewing angle. In an organic light-emitting display device, an OLED is formed at each pixel. The organic light-emitting display device has a high response rate, high luminous efficiency, high luminance, and a large viewing angle and is capable of expressing black gradation in perfect or near perfect black, thereby achieving a high contrast ratio and a high color reproduction rate.

Recently, various optical elements have been added to mobile terminals. The optical elements can include sensors or lighting devices necessary for supporting multi-media functions or performing biometric recognition. The optical element can be assembled below a display panel.

The description provided in the description of the related art section should not be assumed to be prior art merely because it is mentioned in or associated with the description of the related art section. The description of the related art section can include information that describes one or more aspects of the subject technology, and the description in this section does not limit the disclosure.

### SUMMARY OF THE DISCLOSURE

The inventor has realized that, in order to enlarge the screen of a mobile terminal, an optical element can be positioned in a notch region, which is concavely designed at the top of the screen of the display panel, or within a punch hole in the screen. However, since an image is not displayed in such a notch region or punch hole, there can be limitations in achieving a full-screen display design.

Accordingly, an object of the present disclosure can be to solve or address the above-described necessity and/or limitations associated with the related art.

The objectives to be solved or addressed by the example embodiments of this disclosure are not limited to the objectives mentioned above, and other objectives not mentioned will be clearly understood by those skilled in the art from the following descriptions.

A display panel according to aspects of the present disclosure can include a first region including a plurality of pixels having a first pixel density; a second region including a plurality of pixels having a second pixel density that is lower than the first pixel density; a boundary region including a plurality of pixels having a third pixel density that is higher than the second pixel density and equal to the first pixel density, and including a plurality of unit emission regions in which a maximum value among luminance values of respective pixels gradually changes; and a transition region including a plurality of pixels having a fourth pixel density that is higher than the second pixel density and lower than the third pixel density, wherein a boundary between the boundary region and the transition region can include an inflection point where a luminance gradient of pixels changes.

In one example embodiment of the present disclosure, in the boundary region, the maximum value among the luminance values of respective pixels gradually decreases in a direction toward the first region from the boundary region.

In one example embodiment of the present disclosure, an absolute value of an average change in luminance of the pixels in the transition region is smaller than an absolute value of an average change in the luminance of the pixels in the boundary region.

In one example embodiment of the present disclosure, a pixel density, including the first pixel density, the second pixel density, the third pixel density, and the fourth pixel density, can be defined as the number of driven pixels per unit area.

In one example embodiment of the present disclosure, the first region can include a first unit emission region, the second region can include a second unit emission region positioned at one side of the first unit emission region in a first direction, the boundary region can include a third unit emission region positioned at one side of the first unit emission region in the first direction, the transition region can include a fourth unit emission region positioned at one side of the first unit emission region in the first direction, areas of the first to fourth unit emission regions can be the same, and a position of driven pixels in the second unit emission region can correspond to a position of driven pixels in the fourth unit emission region.

In one example embodiment of the present disclosure, one or more ON R pixels, one or more ON B pixels, and one or more ON G pixels.

In one example embodiment of the present disclosure, the first to fourth pixel groups emit light at a same luminance.

In one example embodiment of the present disclosure, the number of driven pixels in the fourth unit emission region can be greater than the number of driven pixels in the second unit emission region and smaller than the number of driven pixels in the third unit emission region.

In one example embodiment of the present disclosure, a maximum value among luminance values of respective pixels arranged in the fourth unit emission region can be greater than or equal to a maximum value among luminance values of respective pixels arranged in the third unit emission region.

In one example embodiment of the present disclosure, the first region can include a first unit emission region, the second region can include a second unit emission region positioned at one side of the first unit emission region in a first direction, the boundary region can include a third unit emission region positioned at one side of the first unit emission region in the first direction, areas of the first to third unit emission regions can be the same, the third unit emission region can include a third-first unit emission region and a third-second unit emission region positioned closer to the first unit emission region than the third-first unit emission region, and a difference between a maximum value among luminance values of respective pixels arranged in the third-first unit emission region and a maximum value among luminance values of respective pixels arranged in the first unit emission region can be greater than a difference between a maximum value among luminance values of respective pixels arranged in the third-second unit emission region and the maximum value among the luminance values of the respective pixels arranged in the first unit emission region.

In one example embodiment of the present disclosure, a maximum value among luminance values of the respective pixels arranged in the second region can be greater than a maximum value among luminance values of the respective pixels arranged in the first region, the boundary region, and the transition region.

In one example embodiment of the present disclosure, a maximum value among luminance values of the respective pixels arranged in the transition region can be greater than a maximum value among luminance values of the respective pixels arranged in the first region.

In one example embodiment of the present disclosure, a maximum value among luminance values of the respective pixels arranged in the boundary region can be greater than a maximum value among luminance values of the respective pixels arranged in the first region.

In one example embodiment of the present disclosure, a maximum value among luminance values of the respective pixels arranged in the transition region can be greater than or equal to a maximum value among luminance values of the respective pixels arranged in the boundary region.

In one example embodiment of the present disclosure, the transition region can include a fourth-first unit emission region and a fourth-second unit emission region positioned closer to the boundary region than the fourth-first unit emission region, and a maximum value among luminance values of respective pixels arranged in the fourth-first unit emission region can be different from a maximum value among luminance values of respective pixels arranged in the fourth-second unit emission region.

In one example embodiment of the present disclosure, the maximum value among the luminance values of the respective pixels arranged in the fourth-first unit emission region can be greater than the maximum value among the luminance values of the respective pixels arranged in the fourth-second unit emission region.

In one example embodiment of the present disclosure, the maximum value among the luminance values of the respective pixels arranged in the fourth-first unit emission region can be smaller than the maximum value among the luminance values of the respective pixels arranged in the fourth-second unit emission region.

In one example embodiment of the present disclosure, the boundary region can be positioned between the first region and the second region, and the transition region can be positioned between the boundary region and the second region.

According to the present disclosure, the degree of reduction or the amount of reduction of the element lifespan and the range of available data voltages can be reduced.

According to the present disclosure, as the power consumption of the display device decreases, low power driving can be enabled.

Objects of the present disclosure are not limited to the above-described object, and other objects of the present disclosure not yet described will be more clearly understood by those skilled in the art from the following detailed description.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a cross-sectional view schematically illustrating a display panel according to one or more example embodiments of the present disclosure;

FIG. 2 is a diagram illustrating an optical element overlapping a second region of a display panel according to one example embodiment of the present disclosure;

FIG. 3 is a diagram illustrating an example of optical elements arranged in a second region and a notch region of a display panel according to one example embodiment of the present disclosure;

FIG. 4 is a block diagram illustrating a display device according to one example embodiment of the present disclosure;

FIG. 5 is a diagram illustrating an example in which a display device according to one example embodiment of the present disclosure is applied to a mobile device;

FIGS. 6 to 8 are circuit diagrams illustrating various pixel circuits applicable to a display device according to one example embodiment of the present disclosure;

FIG. 9 is a plan view illustrating the pixel arrangement of a first region or a boundary region according to one example embodiment of the present disclosure;

FIG. 10 is a plan view illustrating a display panel according to a first example embodiment of the present disclosure;

FIG. 11 is a plan view illustrating a display panel according to a second example embodiment of the present disclosure;

FIG. 12 is a plan view illustrating a display panel according to a third example embodiment of the present disclosure;

FIG. 13 is a diagram illustrating a spatial period of a unit emission region in a display panel according to one example embodiment of the present disclosure;

FIG. 14 is a plan view illustrating a display panel according to a fourth example embodiment of the present disclosure;

FIG. 15 is a diagram illustrating a graph that describes the maximum value among the luminance values of respective pixels with reference to the display panel according to the fourth example embodiment of the present disclosure;

FIG. 16 is a diagram illustrating a graph that describes the maximum value among the luminance values of respective pixels in a display panel according to a fifth example embodiment of the present disclosure;

FIG. 17 is a diagram illustrating a graph that describes the maximum value among the luminance values of respective pixels in a display panel according to a sixth example embodiment of the present disclosure;

FIG. 18 is a diagram illustrating a graph that describes the maximum value among the luminance values of respective pixels in a display panel according to a seventh example embodiment of the present disclosure; and

FIG. 19 is a diagram illustrating a graph that describes an issue of the reduction in the range of data voltages that can be used in a display device.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

The advantages and features of the present disclosure and methods for accomplishing the same will be more clearly understood from embodiments described below with reference to the accompanying drawings. However, the present disclosure is not limited to the following embodiments but can be implemented in various different forms. Rather, the present embodiments will make the disclosure of the present disclosure complete and allow those skilled in the art to completely comprehend the scope of the present disclosure. The present disclosure is only defined within the scope of the accompanying claims.

In describing the present disclosure, if it is determined that the detailed description of the related known technology can unnecessarily obscure the subject matter of the present disclosure, the detailed description thereof will be omitted. When “include,” “have,” “comprise,” “contain,” “constitute,” “make up of,” “formed of,” and “consist of”, or the like mentioned in the present disclosure, other parts can be added unless “only” is used. In the case where the component is expressed in the singular, the plural includes the plural unless specifically stated otherwise.

The shapes, sizes, dimensions (e.g., length, width, height, thickness, radius, diameter, area, etc.), ratios, angles, numbers of elements, and the like illustrated in the accompanying drawings for describing the example embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

It should be interpreted that the components included in the example embodiment of the present disclosure include an error range, although there is no additional particular description thereof.

When describing a positional or interconnected relationship between two components, such as “on”, “above”, “over”, “below”, “under”, “beside”, “beneath”, “near”, “close to,” “adjacent to”, “on a side of”, “next”, “connect or couple with”, “crossing”, “intersecting” etc., one or more other components can be interposed between them unless “immediately” or “directly” is used.

It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the example term “below” can encompass both an orientation of below and above. Similarly, the example term “above” or “over” can encompass both an orientation of “above” and “below”.

When describing a temporal contextual relationship is described, such as “after”, “following”, “next to” or “before”, it may not be continuous on a time scale unless “immediately” or “directly” is used. The terms “first”, “second” and the like can be used to distinguish components from each other, but the functions or structures of the components are not limited by ordinal numbers or component names in front of the components.

The term “at least one” should be understood as including all possible combinations which can be suggested from one or more relevant items. For example, the meaning of “at least one of a first item, a second item, or a third item” can be each one of the first item, the second item, or the third item and also be all possible combinations that can be suggested from two or more of the first item, the second item, and the third item.

A term “device” used herein can refer to a display device including a display panel and a driver for driving the display panel. Examples of the display device can include a light emitting element, and the like. In addition, examples of the device can include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Further, the term “can” fully encompasses all the meanings and coverages of the term “may” and vice versa.

The following embodiments of the present disclosure can be combined or associated with each other in whole or in part, and various types of interlocking and driving are technically possible. The embodiments of the present disclosure can be implemented independently of each other or together in an interrelated relationship.

Terms (including technical and scientific terms) used in the embodiments of the present disclosure can be interpreted in meanings commonly understood by those skilled in the art to which the present disclosure pertains, unless explicitly and specifically defined otherwise, and commonly used terms, such as predefined terms, can be interpreted in consideration of their contextual meanings of the related technology.

In the specification, in adding reference numerals for elements in each drawing, it should be noted that like reference numerals already used to denote like elements in other drawings are used for elements wherever possible. In addition, the dimension scales of constituent elements shown in the drawings can be different from actual dimension scales, for convenience of description. For example, the dimension scales of constituent elements shown in the drawings should not be interpreted to be the same as those shown in the drawings.

In a display device according to aspects of the present disclosure, a pixel circuit and a gate driving circuit can include a plurality of transistors. The transistor can be implemented as a thin film transistor (TFT).

Active layers of the thin-film transistors TFTs can be formed of a semiconductor material, such as an oxide semiconductor, amorphous semiconductor, or polycrystalline semiconductor, but is not limited thereto.

The oxide semiconductor material can have an excellent effect of preventing a leakage current and relatively inexpensive manufacturing cost. The oxide semiconductor can be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor can be made of polycrystalline silicon (poly-Si), but is not limited thereto.

The amorphous semiconductor material can be made of amorphous silicon (a-Si), but is not limited thereto.

For example, the transistor can be an oxide TFT including an oxide semiconductor or a low temperature polysilicon (LTPS) TFT including LTPS.

Hereinafter, example embodiments of the present disclosure will be described in detail with reference to the accompanying drawings. All the components of each display device and each display panel according to all embodiments of the present disclosure are operatively coupled and configured.

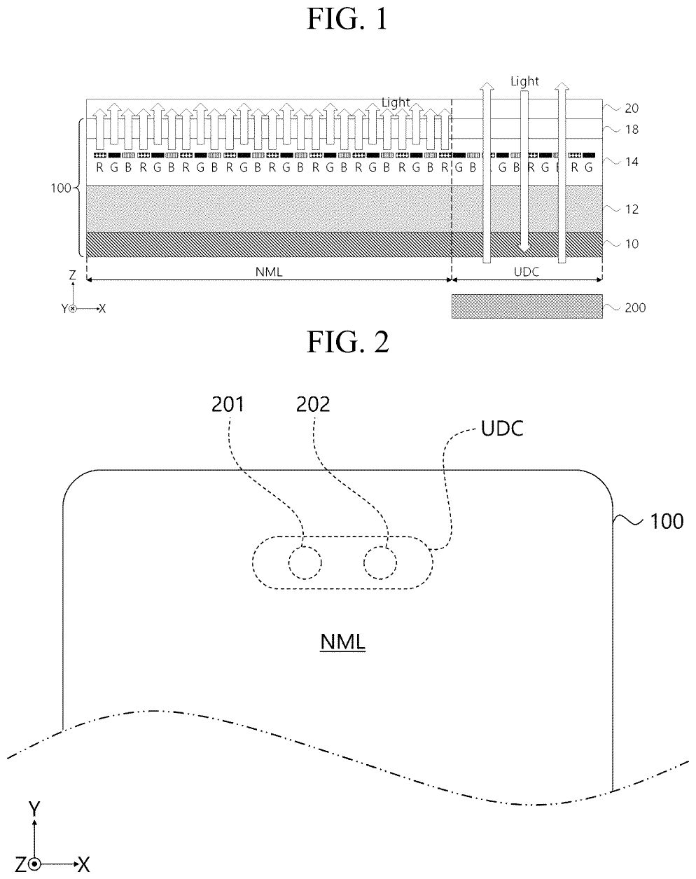

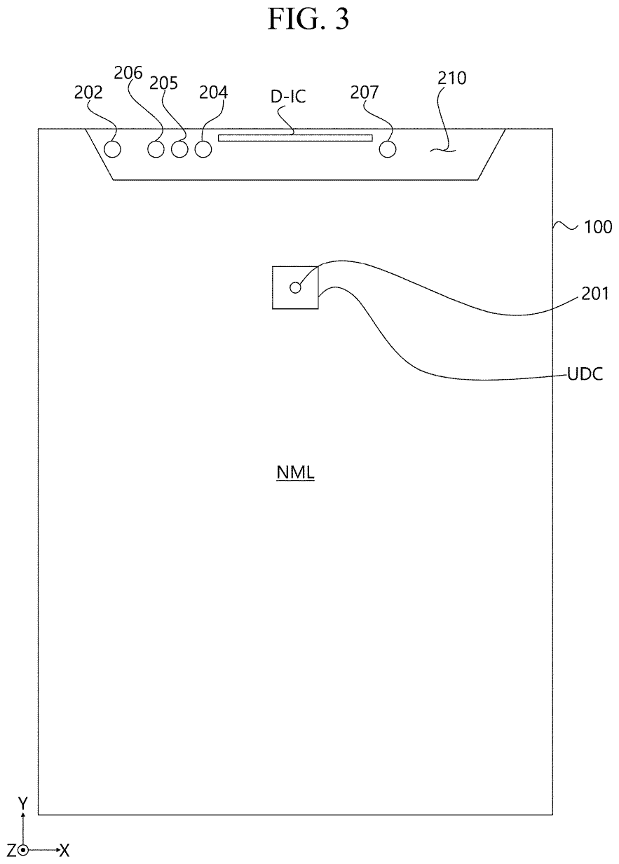

FIG. 1 is a cross-sectional view schematically illustrating a display panel according to one or more example embodiments of the present disclosure. FIG. 2 is a diagram illustrating an optical element overlapping a second region of a display panel according to one example embodiment of the present disclosure. FIG. 3 is a diagram illustrating an example of optical elements arranged in a second region and a notch region of a display panel according to one example embodiment of the present disclosure.

Referring to FIGS. 1 and 2, a pixel array constituting the screen of a display panel 100 according to one example embodiment of the present disclosure can include a first region NML and a second region UDC. The first region NML and the second region UDC can include pixels into which pixel data of an input image is written. The input image can be displayed in the first region NML and the second region UDC.

The first region NML can be a display area in which a plurality of pixels are arranged to reproduce the input image. The first region NML can be larger than the second region UDC and can be a main display area of the screen where most of the image is displayed.

The second region UDC can be a display area where a plurality of pixels are arranged to reproduce the input image. The pixel density or resolution of the second region UDC can be the same or lower than that of the first region NML. Pixel density can be interpreted as pixels per inch (PPI). In the present disclosure, pixel density refers to the number of pixels arranged and driven per the same unit length or area.

The second region UDC can include a plurality of light transmitting portions without a light blocking medium, but is not limited thereto. The light transmitting portion can be positioned between sub-pixels. Light can pass through the light transmitting portion with little loss. If the light transmitting portions of the second region UDC are enlarged to increase the amount of light received by the optical element through the second region UDC, the pixel density of the second region UDC can decrease due to the area of the light transmitting portions, so the pixel density or resolution of the second region UDC can become lower than that of the first region NML.

Each of the pixels in the first region NML and the second region UDC can include sub-pixels of different colors to implement the color of an image. Each of the plurality of subpixels is a minimum unit which configures the display area and n subpixels form one pixel. Each of the plurality of subpixels can emit light having different wavelengths from each other. The plurality of subpixels can include first to third subpixels which emit different color light from each other. For example, the sub-pixels can include red, green, and blue sub-pixels. Meanwhile, the sub-pixels can also include white sub-pixel. The plurality of subpixels can be variously modified in colors and configurations, as necessary. However, the present disclosure is not limited thereto.

For example, the plurality of subpixels can include red, green, and blue subpixels, in which the red, green, and blue subpixels can be disposed in a repeated manner. Alternatively, the plurality of subpixels can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device specifications.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

Hereinafter, the red sub-pixel can be abbreviated as “R sub-pixel”, the green sub-pixel can be abbreviated as “G sub-pixel”, the blue sub-pixel can be abbreviated as “B sub-pixel”, the white sub-pixel can be abbreviated as “W sub-pixel”.

Each of the sub-pixels can include a pixel circuit that drives a light emitting element. For example, the pixel circuit of each of the plurality of subpixels can include a capacitor, at least one thin film transistor, and a light emitting element, such as an OLED. For example, the at least one thin film transistor can include a driving transistor, a first switching transistor, and a second switching transistor. In addition, the light emitting element can include a first electrode/a second electrode (or anode electrode, pixel electrode), an inorganic light emitting layer (or organic light emitting layer), and a second electrode/a first electrode (or cathode electrode, common electrode). However, the pixel circuit of each of the plurality of subpixels are not limited thereto, each of the plurality of subpixels can further include a compensation circuit. In this case, each of the plurality of subpixels can have various structures such as 4T2C, 5T2C, 6T1C, 6T2C, 7T1C, 7T2C, and the like.

At least one optical element 200 can be positioned below the rear surface of the display panel 100 so as to overlap the second region UDC of the display panel 100. External light can travel through the second region UDC to the optical element 200 positioned below the display panel 100. The optical element 200 can include one or more of optical sensors such as an image sensor (or a camera), a proximity sensor, a white light illumination element, and an optical element for facial recognition, but not limited thereto.

The optical element for facial recognition can include an infrared light source, an infrared camera, and an infrared illumination element positioned below the second region UDC of the display panel 10, but not limited thereto.

The reference numeral “201” can denote an infrared light source and the reference numeral “202” can denote an infrared camera, but they are not limited thereto.

Referring to FIG. 3, an ambient light sensor 204, a proximity sensor 205, a flood illuminator 206, the infrared camera 202, and a front camera 207 can be arranged in a notch region 210 of a mobile terminal, and the infrared light source 201 can be arranged in the second region UDC. The notch region 210 can be a non-display area with no pixels at the top of the screen of the mobile terminal.

In the display device according to aspects of the present disclosure, since the optical elements 200 are arranged below the rear surface of the display panel 100 so as to overlap the second region UDC, the display area of the screen may not be restricted by the optical elements 200. Therefore, the display device according to the present disclosure can implement a full-screen display by enlarging the display area of the screen, and can increase the degree of freedom in screen design.

The display panel 100 can have a width in an X-axis direction, a length in a Y-axis direction, and a thickness in a Z-axis direction, but not limited thereto. For example, the display panel 100 can have a width in a Y-axis direction, a length in an X-axis direction, and a thickness in a Z-axis direction. The X-axis direction and the Y-axis direction can intersect each other on the plane of the display panel 100. For example, the X-axis direction and the Y-axis direction can be orthogonal to each other, but not limited thereto.

The display panel 100 can include a circuit layer 12 positioned on a substrate, and a light emitting element layer 14 positioned on the circuit layer 12. A polarizing plate 18 can be positioned on the light emitting element layer 14, and a cover glass 20 can be positioned on the polarizing plate 18.

The circuit layer 12 can include a pixel circuit connected to wires such as data lines, gate lines intersecting the data lines, and power lines, and a gate driver connected to the gate lines. The circuit layer 12 can include circuit elements such as transistors implemented as thin film transistors (TFTs) and a capacitor. The circuit elements and wiring of the circuit layer 12 can be implemented with a plurality of insulating layers, two or more metal layers separated by the insulating layers interposed therebetween, and an active layer including a semiconductor material.

The light emitting element layer 14 can include a light emitting element driven by the pixel circuit. The light emitting element can be implemented as an OLED. The OLED can include an organic compound layer formed between an anode and a cathode. The organic compound layer can include a hole injection layer (HIL), a hole transport layer (HTL), an emission layer (EML), an electron transport layer (ETL), and an electron injection layer (EIL), but is not limited thereto. When a voltage is applied to the anode electrode and cathode electrode of the OLED, holes that have passed through the hole transport layer (HTL) and electrons that have passed through the electron transport layer (ETL) move to the emission layer (EML) to form excitons, thereby allowing visible light to be emitted from the emission layer (EML). The OLED used as the light emitting element can have a tandem structure in which a plurality of emission layers are stacked. The OLED with a tandem structure can improve the luminance and lifespan of the pixels. The light emitting element layer 14 can further include a color filter array positioned above the light emitting element to selectively transmit red, green, and blue wavelengths.

The light emitting element layer 14 can be covered with a protective layer, and the protective layer can be covered with an encapsulation layer. The protective layer and the encapsulation layer can have a multi-insulating film structure in which organic and inorganic films are alternately stacked. The inorganic film can block the permeation of moisture or oxygen. The organic film can planarize the surface of the inorganic film. When the organic and inorganic films are stacked in multiple layers, the movement path of moisture or oxygen can become longer than that in a single layer, effectively blocking the permeation of moisture and oxygen affecting the light emitting element layer 14.

For example, the encapsulation layer can include a first inorganic encapsulation layer, a first organic encapsulation layer, and a second inorganic encapsulation layer. Alternatively, the encapsulation layer can include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer can serve to block the penetration of moisture or oxygen. The first inorganic encapsulation layer, the second inorganic encapsulation layer, and the third inorganic encapsulation layer can be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer can each have a larger thickness than each of the first inorganic encapsulation layer, the second inorganic encapsulation layer, and the third inorganic encapsulation layer in order to adsorb or block particles that can be produced during a process of manufacturing the display device. The first organic encapsulation layer and the second organic encapsulation layer can fill cracks that can be formed in the first inorganic encapsulation layer and the second inorganic encapsulation layer. The first organic encapsulation layer and the second organic encapsulation layer can planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer can planarize an upper portion of the first inorganic encapsulation layer by covering particles on the first inorganic encapsulation layer. For example, the second organic encapsulation layer can planarize an upper portion of the second inorganic encapsulation layer by covering particles on the second inorganic encapsulation layer. The first organic encapsulation layer and the second organic encapsulation layer can be made of an organic material, and for example, epoxy polymer, acrylic polymer, or the like can be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) can be included.

A touch sensor layer can be formed on the encapsulation layer, and the polarizing plate 18 or a color filter layer can be positioned on the touch sensor layer. The touch sensor layer can include capacitive touch sensors that sense touch input based on changes in capacitance before and after a touch input. The touch sensor layer can include metal wiring patterns and insulating films that form the capacitance of the touch sensors. The insulating films can insulate an intersecting portion in the metal wiring patterns and planarize the surface of the touch sensor layer.

The polarizing plate 18 can convert the polarization of external light reflected by the metal of the touch sensor layer and the circuit layer to improve visibility and contrast. The polarizing plate 18 can be implemented as a linear polarizing plate bonded with a phase retardation film or a circular polarizing plate. The cover glass 20 can be bonded onto the polarizing plate 18. The color filter layer positioned on the touch sensor layer can include red, green, and blue color filters. The color filter layer can further include a black matrix pattern. The color filter layer can absorb a portion of the wavelength of light reflected from the circuit layer and the touch sensor layer, thereby serving as a substitute for the polarizing plate 18 and increasing the color purity of the image reproduced in the pixel array. In this case, the polarizing plate 18 may not be provided.

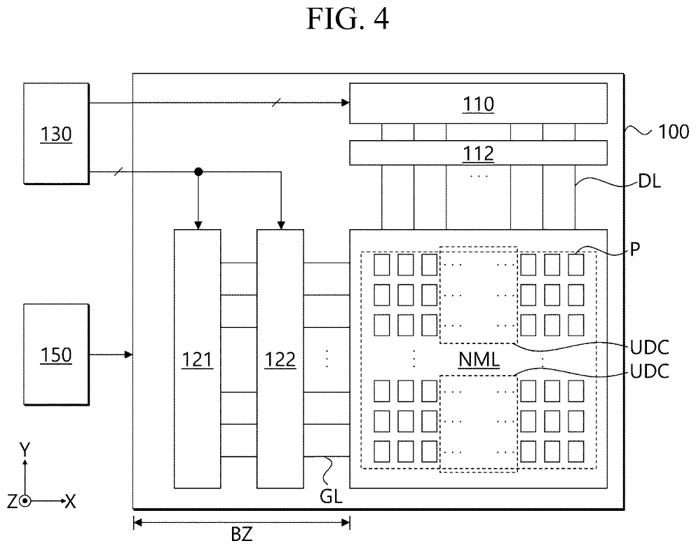

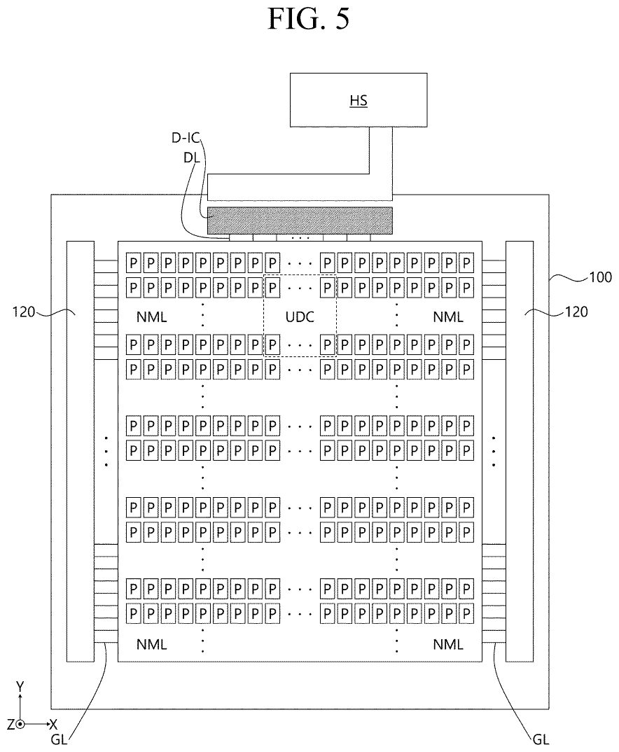

FIG. 4 is a block diagram illustrating a display device according to one example embodiment of the present disclosure. FIG. 5 is a diagram illustrating an example in which a display device according to one example embodiment of the present disclosure is applied to a mobile device.

Referring to FIGS. 4 and 5, the display device according to one example embodiment of the present disclosure can include the display panel 100, a display panel driver 110, 120 for writing the pixel data of the input image to pixels P of the display panel 100, a timing controller 130 for controlling the display panel driver, and a power supply 150 for generating power necessary for driving the display panel 100.

The display panel 100 can include a pixel array for displaying the input image on the screen. The pixel array can be divided into the first region NML and the second region UDC as described above.

The touch sensors can be arranged on the screen of the display panel 100.

The display panel 100 can be implemented as a flexible display panel in which the pixels P are arranged on a flexible substrate such as a plastic substrate or a metal substrate. For example, the substrate can include a flexible polymer film. For example, the flexible polymer film can be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto.

The display panel driver can reproduce the input image on the screen of the display panel 100 by writing the pixel data of the input image to the sub-pixels. The display panel driver can include a data driver 110 and a gate driver 120. The display panel driver can further include a demultiplexer 112 positioned between the data driver 110 and data lines DL.

The display panel driver can operate in a low-speed driving mode under the control of the timing controller 130.

The data driver 110 can convert the pixel data of the input image, which is digital data, using a digital-to-analog converter (hereinafter referred to as “DAC”) to generate a data voltage Vdata. The data voltage Vdata outputted from each of the channels of the data driver 110 can be supplied to the data lines DL of the display panel 100, or can be supplied to the data lines DL through the demultiplexer 112.

The demultiplexer 112 can distribute the data voltage Vdata outputted through the channels of the data driver 110 to the plurality of data lines DL in a time-division manner. The number of channels of the data driver 110 can be reduced due to the demultiplexer 112.

The gate driver 120 can shift a gate signal using a shift register to sequentially supply the signals to gate lines GL.

The gate driver 120 can be arranged on each of the left and right bezels of the display panel 100 and supply the gate signals to the gate lines GL in a double feeding manner.

The gate driver 120 can include a first gate driver 121 and a second gate driver 122. The first gate driver 121 can output a scan pulse and a sensing pulse, and can shift the scan pulse and the sensing pulse according to a shift clock. The second gate driver 122 can output an EM pulse and can shift the EM pulse according to the shift clock.

The timing controller 130 can receive the pixel data of the input image and a timing signal synchronized with the pixel data from a host system HS. The timing signal can include a vertical synchronization signal Vsync, a horizontal synchronization signal Hsync, a clock CLK, and a data enable signal DE. Here, the horizontal synchronization signal is a signal representing a time taken to display one horizontal line of a screen and the vertical synchronization signal is a signal representing a time taken to display a screen of one frame. The data enable signal can correspond to a signal indicating a period for which a data voltage is supplied to the pixel.

The timing controller 130 can transmit the pixel data of the input image to the data driver 110 and can synchronize the data driver 110, the demultiplexer 112, and the gate driver 120.

The timing controller 130 can multiply an input frame frequency by i (i being a positive integer greater than zero) to control the operation timing of the display panel driver 110, 112, and 120 at a frame frequency of the input frame frequency×i Hz.

Based on the timing signal Vsync, Hsync, and DE received from the host system HS, the timing controller 130 can generate a data timing control signal for controlling the operation timing of the data driver 110, and a gate timing control signal for controlling operation timing of the gate driver 120.

The timing controller 130 can be configured to be coupled with various processors, for example, a microprocessor, a mobile processor, an application processor, etc. in accordance with a device mounted therein.

The timing controller 130 can be implemented in a separate component from the data driver 110, or integrated with the data driver 110, so that the timing controller 130 and the data driver 110 can be implemented in a single integrated circuit.

The timing controller 130 can be a timing controller used in the typical display technology or a control apparatus/device capable of additionally performing other control functionalities in addition to the typical function of the timing controller. In one or more embodiments of the present disclosure, the timing controller 130 can be one or more other control circuits different from the timing controller, or a circuit or component in the control apparatus/device. The timing controller 130 can be implemented using various circuits or electronic components such as an integrated circuit (IC), a field programmable gate array (FPGA), an application specific integrated circuit (ASIC), a processor, and/or the like.

The timing controller 130 can be mounted on a printed circuit board, a flexible printed circuit, or the like, and can be electrically connected to the data driver 110 and the gate driver 120 through the printed circuit board, the flexible printed circuit, and/or the like.

The timing controller 130 can transmit signals to, and receive signals from, the data driver 110 via one or more predetermined interfaces. For example, such interfaces can include a low voltage differential signaling (LVDS) interface, an embedded clock point-point interface (EPI), a serial peripheral interface (SPI), and the like. However, the present disclosure are not limited thereto.

The voltage level of the gate timing control signal outputted from the timing controller 130 can be converted to a gate high voltage VGH/VEH and a gate low voltage VGL/VEL through a level shifter, which is omitted from the drawings, and supplied to the gate driver 120. The level shifter can receive a clock of the gate timing control signal from the timing controller 130 and output a timing signal, such as a start pulse and a shift clock, necessary for driving the gate driver 120.

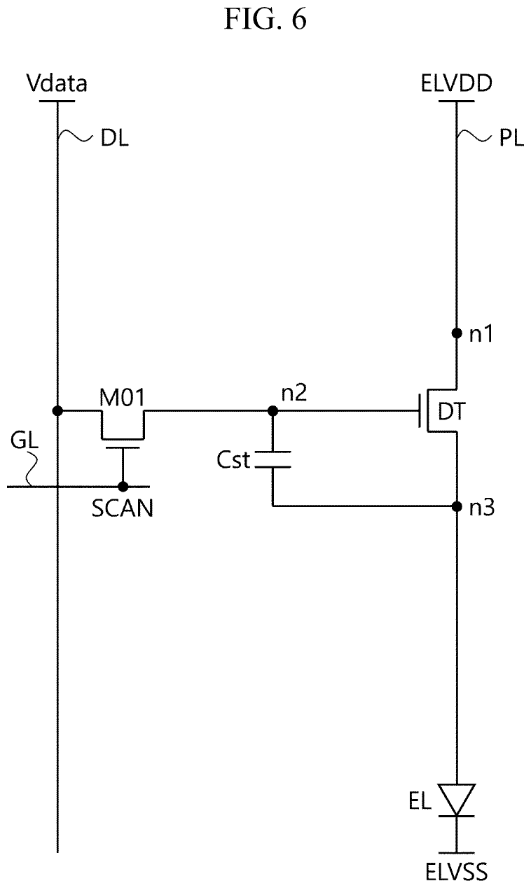

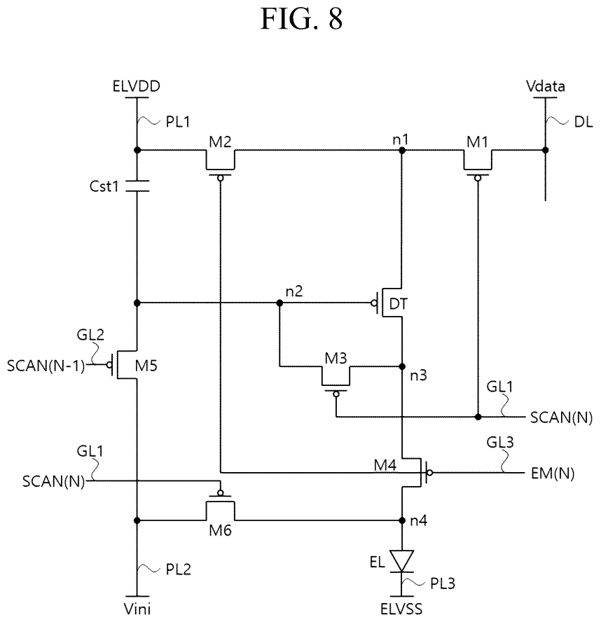

The power supply 150 can adjust a DC input voltage from the host system HS to generate power necessary for driving the display panel 100 and the display panel driver. The power supply 150 can output DC voltages such as a gamma reference voltage, a gate-off voltage VGH/VEH, a gate-on voltage VGL/VEL, a pixel driving voltage ELVDD (see FIG. 6), a low potential power voltage ELVSS (see FIG. 6), an initialization voltage Vini (see FIG. 8), and a reference voltage VREF.

The host system HS can be a main circuit board of a television (TV) system, a set-top box, a navigation system, a personal computer (PC), a vehicle system, a home theater system, a mobile device, or a wearable device. The host system HS can include an authentication module.

FIGS. 6 to 8 are circuit diagrams illustrating various pixel circuits applicable to a display device according to one example embodiment of the present disclosure.

Referring to FIG. 6, the pixel circuit can include a light emitting element EL, a driving element DT that supplies a current to the light emitting element EL, a switch element M01 that connects the data line DL to a second node n2 in response to a scan pulse SCAN, and a capacitor Cst connected between the second node n2 and a third node n3. The driving element DT and the switch element M01 can be implemented as n-channel transistors. However, the present disclosure is not limited thereto, the driving element DT and the switch element M01 can also be implemented as p-channel transistors.

The driving element DT can include a gate electrode connected to the second node n2, a first electrode connected to a first node n1, and a second electrode connected to the third node n3. A VDD line PL, to which the pixel driving voltage ELVDD is applied, can be connected to the first node n1. The light emitting element EL can include an anode electrode connected to the third node n3, and a cathode electrode connected to a VSS line to which the low potential power voltage ELVSS is applied.

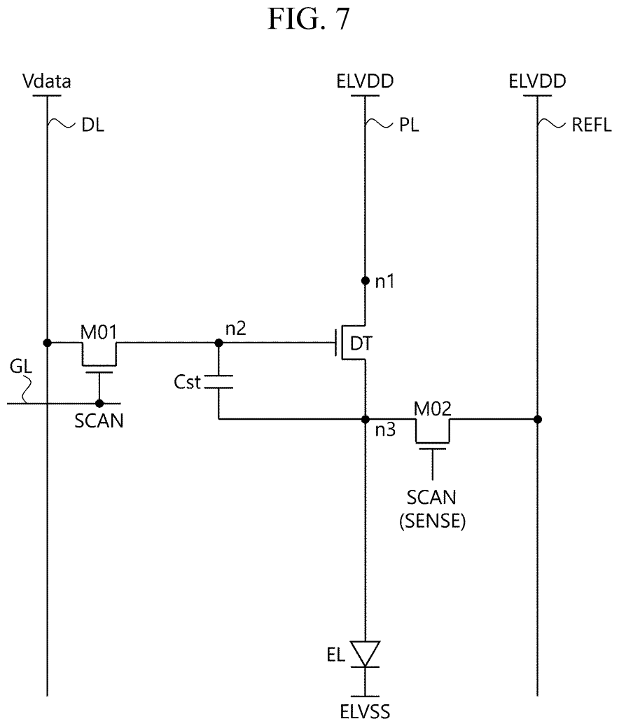

Referring to FIG. 7, the pixel circuit can further include a second switch element M02 connected between a reference voltage line REFL and the second electrode of the driving element DT. In this pixel circuit, the driving element DT and the switch elements M01 and M02 can be implemented as n-channel transistors. However, the present disclosure is not limited thereto, the driving element DT and the switch elements M01 and M02 can also be implemented as p-channel transistors.

Referring to FIG. 8, the pixel circuit can include a light emitting element EL, a driving element DT that supplies a current to the light emitting element EL, and a switching circuit that switches voltages applied to the light emitting element EL and the driving element DT.

The switching circuit can include an internal compensation circuit that samples a threshold voltage Vth of the driving element DT using a plurality of switch elements M1 to M6 to store it in a capacitor Cst1, and compensates the gate voltage of the driving element DT by the threshold voltage Vth of the driving element DT. Each of the driving element DT and the switch elements M1 to M6 can be implemented as a p-channel TFT. However, the present disclosure is not limited thereto, each of the driving element DT and the switch elements M1 to M6 can also be implemented as a n-channel TFT.

The anode electrode of the light emitting element EL can be connected to a fourth node n4 between a fourth switch element M4 and a sixth switch element M6. The fourth node n4 can be connected to the anode electrode of the light emitting element EL, the second electrode of the fourth switch element M4, and the second electrode of the sixth switch element M6. The cathode electrode of the light emitting element EL can be connected to a VSS line PL3 to which the low potential power voltage ELVSS is applied.

The capacitor Cst1 can be connected between a VDD line PL1 and a second node n2.

The driving element DT can drive the light emitting element EL by adjusting the current flowing through the light emitting element EL according to a gate-to-source voltage Vgs. The driving element DT can include a gate electrode connected to the second node n2, a first electrode connected to a first node n1, and a second electrode connected to a third node n3.

It should be noted that the pixel circuit is not limited to those shown in FIGS. 6 to 8. For example, the data voltage Vdata can be applied to the gate electrode of the driving element DT, or can be applied to the first electrode or second electrode of the driving element DT.

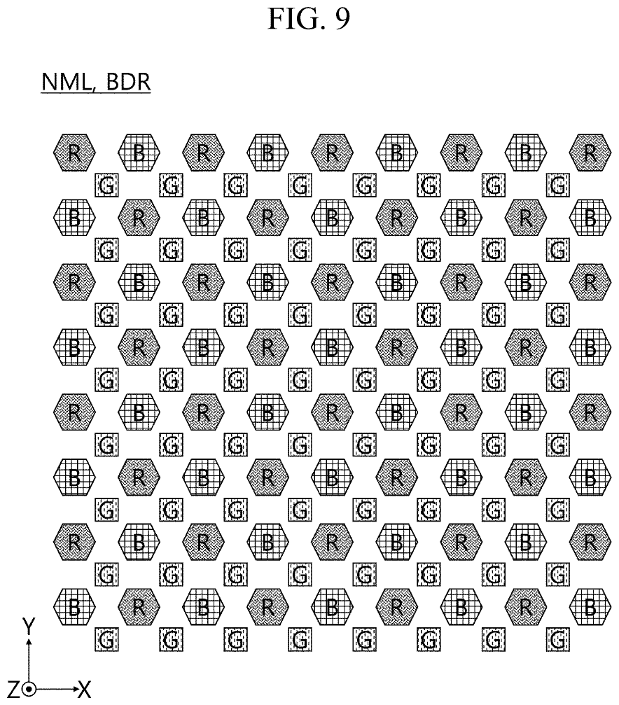

FIG. 9 is a plan view illustrating the pixel arrangement of a first region or a boundary region according to one example embodiment of the present disclosure.

Referring to FIG. 9, the first region NML can include the plurality of pixels. Each of the pixels can be implemented as a real-type pixel in which R, G, and B sub-pixels of the three primary colors constitute a single pixel. Each of the pixels can further include a W sub-pixel, which is omitted from the drawing.

The pixel density or resolution of the first region NML can be higher than the pixel density or resolution of the second region. As will be described later, the reference symbol for the second region is UDC.

Each of the pixels can be configured as a pixel composed of two sub-pixels using a sub-pixel rendering algorithm. For example, a first pixel can be composed of an R sub-pixel and a first G sub-pixel, and a second pixel can be composed of a B sub-pixel and a second G sub-pixel. In each of the first and second pixels, the deficiency in color representation can be compensated by averaging the corresponding color data among adjacent pixels.

The sub-pixels can have different luminous efficiencies of the light emitting elements depending on the color. In consideration of this, the sizes of the sub-pixels can differ depending on their colors. For example, among the R, G, and B sub-pixels, the B sub-pixel can be the largest and the G sub-pixel can be the smallest.

Hereinafter, descriptions will be provided regarding the first region NML, the second region UDC, a boundary region BDR, and a transition region, which can be included in the display panel according to one example embodiment of the present disclosure.

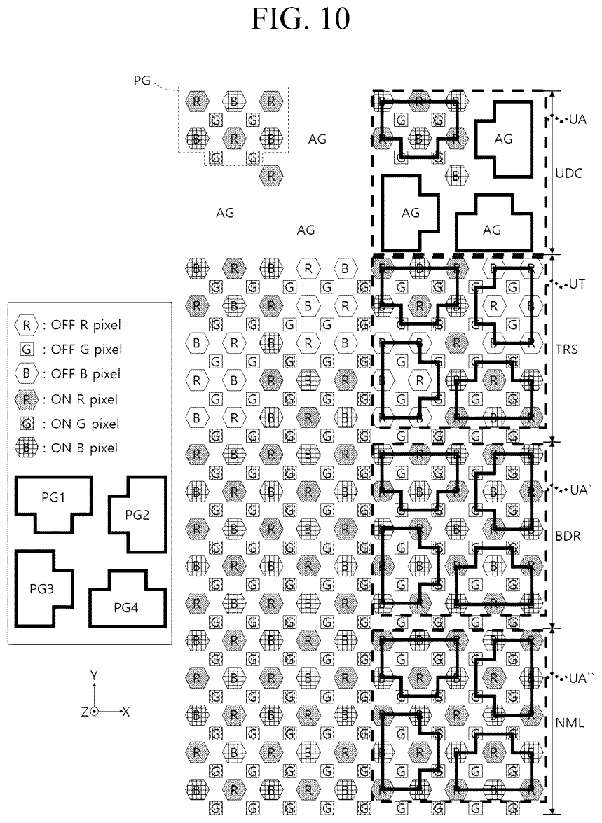

FIG. 10 is a plan view illustrating a display panel according to a first example embodiment of the present disclosure.

Referring to FIG. 10, the display panel can include the first region NML, the second region UDC, a boundary region BDR, and a transition region TRS.

In the following, concepts for each region and a plurality of unit emission regions will be described, focusing on pixel density, the number of arranged pixels, the number of driven pixels, and the positions where pixel groups PG driven in the same unit emission region are arranged. The maximum value among the luminance values of the respective pixels arranged in each region according to some example embodiments of the present disclosure will be described later with reference to the accompanying drawings.

The first region NML can be a region excluding the second region UDC, which overlaps the light emitting element positioned below the display panel, and the transition region TRS and the boundary region BDR, which are arranged to improve the visibility of the second region UDC. The first region NML can serve as the main display area of the screen where most of an image is displayed.

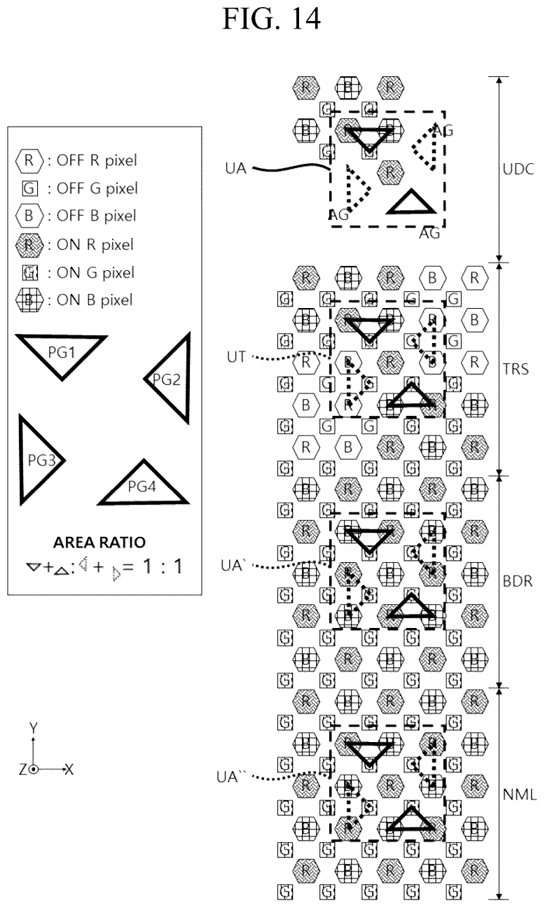

The first region NML can include the pixel groups PG spaced apart by a selected distance. The pixel groups PG are not limited to those shown in the drawings, as will be described later. For example, the pixel groups PG can be grouped in substantially the same or similar manner as shown in FIG. 10 or FIG. 14.

The pixel group PG can include a plurality of pixels and can emit light at a luminance corresponding to the gradation of the pixel data. Each of the plurality of pixels can include two to four sub-pixels, but is not limited thereto. For example, the first pixel can be composed of R and G sub-pixels, and the second pixel can be composed of B and G sub-pixels, but they are not limited thereto. An emission region in the pixel group PG can be determined as the total sum of the emission regions connected to the sub-pixels in the pixel group PG.

The shape and size of the emission region of each color in each pixel can be determined by a fine metal mask (FMM). The emission regions for each color in the pixel group PG of the first region NML can be designed to be substantially the same as those of the second region UDC, or can be designed in a different shape and/or size from the emission regions of the first region NML by using the FMM of a different shape from that used in the first region NML.

As described above, pixel density can be defined herein as the number of driven pixels per unit area. The number of driven pixels can be based on the premise that the pixels are arranged in a corresponding unit area. Accordingly, a higher pixel density can be based on the premise that a greater number of pixels are arranged in a corresponding unit area. However, since not all arranged pixels are driven, a larger number of arranged pixels may not necessarily indicate a higher pixel density. Additionally, pixel density can be an indicator that only reflects whether the arranged pixels are driven, based on the assumption that the pixels are arranged, and may not reflect the luminance level.

A plurality of pixels having a first pixel density can be arranged in the first region NML. The pixels can all be ON pixels (ON R PIXEL, ON G PIXEL, and ON B PIXEL). The ON pixels (ON R PIXEL, ON G PIXEL, and ON B PIXEL) can be arranged at corresponding locations and selectively activated according to the input image. OFF pixels (OFF R PIXEL, OFF G PIXEL, and OFF B PIXEL) can be deactivated regardless of the input image. The ON pixels (ON R PIXEL, ON G PIXEL, and ON B PIXEL) and the OFF pixels (OFF R PIXEL, OFF G PIXEL, and OFF B PIXEL) are all based on the premise that the pixels are arranged. Since the OFF pixels (OFF R pixel, OFF G pixel, and OFF B pixel) are merely in an inactive state despite being arranged, they can be activated and turned into ON pixels (ON R pixel, ON G pixel, and ON B pixel) depending on a user and/or model. The pixels arranged in the first region NML can all be ON pixels (ON R pixel, ON G pixel, and ON B pixel) that are driven. The first pixel density can be the highest on the display panel, but not limited thereto.

The first region NML can include a first unit emission region UA″. The pixels arranged in the first unit emission region UA″ can all be ON pixels (ON R PIXEL, ON G PIXEL, and ON B PIXEL).

The second region UDC can include the pixel groups PG spaced apart by a selected distance, and light transmitting portions AG arranged between adjacent pixel groups PG. Due to the light transmitting portions AG, a separation distance between the pixel groups PG in the second region UDC can be greater than a separation distance between the pixel groups PG in the first region NML. The pixel group PG represented by a region indicated by a dotted line of FIG. 10 can include a plurality of sub-pixels.

The light transmitting portions AG can be areas without pixels. The light transmitting portions AG can include transparent insulating materials without including a metal wire or pixels. Due to the light transmitting portions AG, the pixel density of the second region UDC can decrease, but the average light transmittance of the second region UDC can be higher than that of the first region NML, thereby increasing the amount of light received by the optical elements. The light transmitting portions AG are illustrated as having an angular shape, but are not limited thereto. For example, the light transmitting portions AG can be designed in various shapes, such as circular, elliptical, or polygonal shapes.

A plurality of pixels having a second pixel density can be arranged in the second region UDC. The second pixel density can be lower than the first pixel density due to the light transmitting portions AG. Since no pixels are arranged in the light transmitting portions AG, the pixels arranged in the second region UDC can all be ON pixels (ON R PIXEL, ON G PIXEL, and ON B PIXEL). The pixels arranged in the second region UDC can all be ON pixels (ON R PIXEL, ON G PIXEL, and ON B PIXEL) those are driven. The second pixel density can be the lowest on the display panel, but not limited thereto.

The second region UDC can include a second unit emission region UA. The second unit emission region UA can be positioned at one side of the first unit emission region UA″ in a first direction (e.g., in the Y-axis direction). The area of the second unit emission region UA can be the same as the area of the first unit emission region UA″. Since the second unit emission region UA includes the light emitting portion AG, the number of driven pixels in the second unit emission region UA can be smaller than the number of driven pixels in the first unit emission region UA″. The pixels arranged in the second unit emission region UA can all be ON pixels (ON R PIXEL, ON G PIXEL, and ON B PIXEL).

The display panel can include the boundary region BDR and the transition region TRS of a selected size, which are positioned between the first region NML and the second region UDC. The transition region TRS can be positioned between the boundary region BDR and the second region UDC. Each of the boundary region BDR and the transition region TRS can include a plurality of pixels. As the display panel includes the boundary region BDR and/or the transition region TRS, a phenomenon in which the boundary between the first region NML and the second region UDC is visually recognized can be improved.

A plurality of pixels having a third pixel density can be arranged in the boundary region BDR. The third pixel density can be higher than the second pixel density. The third pixel density can be substantially the same as the first pixel density, but is not limited thereto, and in one example embodiment, the third pixel density can be lower than the first pixel density. The pixels arranged in the boundary region BDR can all be ON pixels (ON R PIXEL, ON G PIXEL, and ON B PIXEL). The pixels arranged in the boundary region BDR can all be ON pixels (ON R PIXEL, ON G PIXEL, and ON B PIXEL) that are driven. The third pixel density can be the highest on the display panel, but not limited thereto.

The boundary region BDR can include a third unit emission region UA′. The third unit emission region UA′ can be positioned at one side of the first unit emission region UA″ in the first direction (e.g., in the y-axis direction). The area of the third unit emission region UA′ can be the same as the area of the first unit emission region UA″. The number of driven pixels in the third unit emission region UA′ can be greater than the number of driven pixels in the second unit emission region UA. The number of driven pixels in the third unit emission region UA′ can be substantially the same as the number of driven pixels in the first unit emission region UA″. The pixels arranged in the third unit emission region UA′ can all be ON pixels (ON R PIXEL, ON G PIXEL, and ON B PIXEL).

The boundary region BDR is defined as a region in which the maximum value among the luminance values of the respective pixels arranged therein gradually changes, and a description thereof will be provided later.

A plurality of pixels having a fourth pixel density can be arranged in the transition region TRS. The fourth pixel density can be higher than the second pixel density. The fourth pixel density can be lower than the third pixel density. The fourth pixel density can be lower than the first pixel density. The pixels arranged in the transition region TRS can include ON pixels (ON R PIXEL, ON G PIXEL, and ON B PIXEL) and OFF pixels (OFF R PIXEL, OFF G PIXEL, and OFF B PIXEL). At least one of the pixels arranged in the transition region TRS may not be driven. The fourth pixel density can be higher than the second pixel density and lower than the third pixel density, but not limited thereto.

The transition region TRS can include a fourth unit emission region UT. The fourth unit emission region UT can be positioned at one side of the first unit emission region UA″ in the first direction (e.g., the Y-axis direction). The area of the fourth unit emission region UT can be the same as the area of the first unit emission region UA″. The number of driven pixels in the fourth unit emission region UT can be greater than or equal to the number of driven pixels in the second unit emission region UA. The number of driven pixels in the fourth unit emission region UT can be smaller than the number of driven pixels in the third unit emission region UA′. The pixels arranged in the fourth unit emission region UT can include ON pixels (ON R PIXEL, ON G PIXEL, and ON B PIXEL) and OFF pixels (OFF R PIXEL, OFF G PIXEL, and OFF B PIXEL).

The transition region TRS can have a greater number of pixels arranged per unit area than the second region UDC. Additionally, the number of driven pixels in the transition region TRS can be greater than that in the second region UDC. The transition region TRS may not include the light transmitting portion AG. As shown in FIG. 10, at the boundary between the transition region TRS and the second region UDC, a portion including the light transmitting portion AG can be classified as the second region UDC, and a portion not including the light transmitting portion AG can be classified as the transition region TRS.

Each of the second unit emission region UA, the fourth unit emission region UT, the third unit emission region UA′, and the first unit emission region UA″ can be provided with substantially the same size or area. Each of them can be divided into pixel groups PG1, PG2, PG3, and PG4 having substantially the same size or area. When divided into the pixel groups PG1, PG2, PG3, and PG4, there can be a pixel that is not included in any of the pixel groups such that their sizes or areas are formed to be the same. For example, the first region NML can include the first unit emission region UA″. The first unit emission region UA″ can include first to fourth pixel groups PG1, PG2, PG3, and PG4, each having three ON R pixels, three ON B pixels, and four ON G pixels. An ON R pixel surrounded by them may not be included in any of the pixel groups. Since the ON R pixel is a pixel left over in the process of dividing into the pixel groups having the same area, it can be derived to be included in all of the pixel groups. For example, the first unit emission region UA″ can include the first to fourth pixel groups PG1, PG2, PG3, and PG4, each having four ON R pixels, three ON B pixels, and four ON G pixels. The remaining pixel may not be included in any of the pixel groups or can be commonly included in all of the pixel groups.

In the second unit emission region UA, pixels can be arranged in a portion where the first pixel group PG1 is positioned, and the pixels arranged in the first pixel group PG1 can be driven. In the fourth unit emission region UT, pixels can be arranged in portions where the first to fourth pixel groups PG1, PG2, PG3, and PG4 are positioned, and the pixels arranged in the first pixel group PG1 and the fourth pixel group PG4 can be driven.

In the second unit emission region UA, positions where the ON pixels (ON R PIXEL, ON G PIXEL, and ON B PIXEL) are arranged can correspond to the portion where the first pixel group PG1 is positioned. In the fourth unit emission region UT, the positions where the ON pixels (ON R PIXEL, ON G PIXEL, and ON B PIXEL) are arranged can correspond to portions where the first pixel group PG1 and the fourth pixel group PG4 are positioned.

In the fourth unit emission region UT, positions where the driven pixels are arranged can correspond to the portions where the first pixel group PG1 and the fourth pixel group PG4 are positioned, and in the second unit emission region UA, positions where the driven pixels are arranged can correspond to the portion where the first pixel group PG1 is positioned.

The transition region TRS can have substantially the same number of pixels arranged per unit area as the boundary region BDR. The transition region TRS can have a smaller number of driven pixels per unit area than the boundary region BDR.

In the first region NML, the second region UDC, the boundary region BDR, and the transition region TRS, the number of pixels arranged per unit area can vary, and/or the number of driven pixels per unit area can vary, and/or the pixel density can vary, and/or the maximum value among the luminance values of the respective pixels included in each region can vary, and/or the maximum value among the luminance values of the respective pixels included in the first to fourth unit emission regions UT can vary.

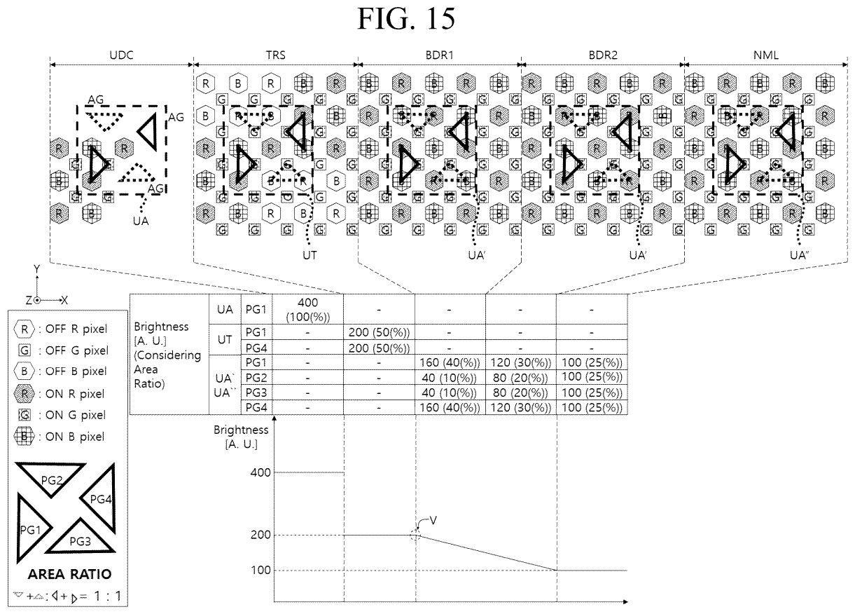

A description related to luminance will be provided later with reference to a graph and the like (see FIG. 15 and subsequent figures).

In the present disclosure, the first region NML, the second region UDC, the boundary region BDR, and the transition region TRS can include the plurality of pixels. The maximum value among the luminance values of the respective pixels refers to the maximum value among the luminance values of the pixels arranged in each of the above regions. The first to fourth unit emission regions UA″, UA, UA′, and UT can include the plurality of pixels. The maximum value among the luminance values of the respective pixels refers to the maximum value among the luminance values of the pixels arranged in each of the above regions.

In the display panel according to the present disclosure, at least one of the number of pixels arranged and driven per unit area, the pixel density, or the maximum value among the luminance values of the respective pixels driven in each region can be adjusted, thereby improving a phenomenon in which the boundary between the first region NML and the second region UDC is visually recognized. In addition, since the aforementioned optical element can be positioned below the screen on which an image is displayed, the sense of heterogeneity that can occur due to the boundary being visually recognized can be reduced or prevented, and a full-screen display can be implemented.

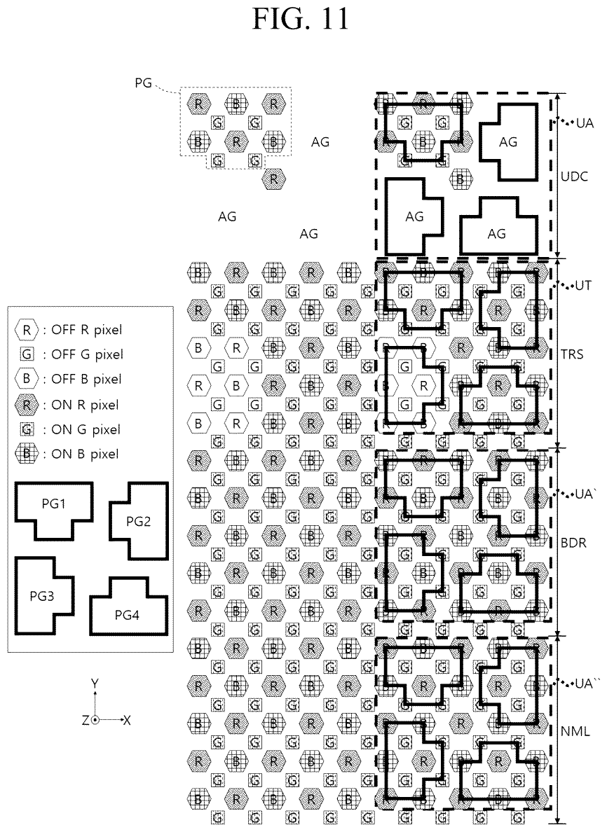

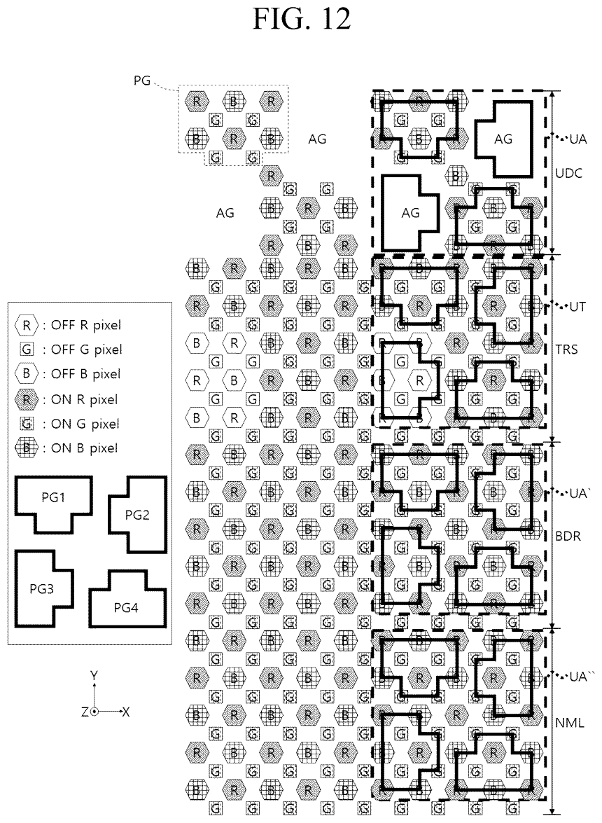

FIG. 11 is a plan view illustrating a display panel according to a second example embodiment of the present disclosure. FIG. 12 is a plan view illustrating a display panel according to a third example embodiment of the present disclosure. A detailed description of configurations that perform substantially the same function as the first example embodiment described above will be omitted.

Referring to FIG. 11, in the second unit emission region UA, the pixels can be arranged in a portion where the first pixel group PG1 is positioned, and the pixels arranged in the first pixel group PG1 can be driven, and the pixels arranged in the second pixel group PG2, the third pixel group PG3 and the fourth pixel group PG4 may not be driven. In the fourth unit emission region UT, the pixels can be arranged in portions where the first to fourth pixel groups PG1, PG2, PG3, and PG4 are positioned, and the pixels arranged in the first pixel group PG1, the second pixel group PG2, and the fourth pixel group PG4 can be driven, and the pixels arranged in the third pixel group PG3 may not be driven. However, the present disclosure is not limited thereto, in the fourth unit emission region UT, the pixels can be arranged in portions where the first to fourth pixel groups PG1, PG2, PG3, and PG4 are positioned, and the pixels arranged in at least one of the first pixel group PG1, the second pixel group PG2, and the fourth pixel group PG4 can be driven.

In the second unit emission region UA, positions where the ON pixels (ON R PIXEL, ON G PIXEL, and ON B PIXEL) are arranged can correspond to the portion where the first pixel group PG1 is positioned. In the fourth unit emission region UT, positions where the ON pixels (ON R PIXEL, ON G PIXEL, and ON B PIXEL) are arranged can correspond to portions where the first pixel group PG1, the second pixel group PG2, and the fourth pixel group PG4 are positioned.

In the fourth unit emission region UT, positions where the driven pixels are arranged can correspond to the portions where the first pixel group PG1, the second pixel group PG2, and the fourth pixel group PG4 are positioned, and in the second unit emission region UA, positions where the driven pixels are arranged can correspond to the portion where the first pixel group PG1 is positioned.

Referring to FIG. 12, in the second unit emission region UA, the pixels are arranged in portions where the first pixel group PG1 and the fourth pixel group PG4 are positioned, and the pixels arranged in the first pixel group PG1 and the fourth pixel group PG4 can be driven, and the pixels arranged in the second pixel group PG2 and the third pixel group PG3 may not be driven. In the fourth unit emission region UT, the pixels are arranged in portions where the first to fourth pixel groups PG1, PG2, PG3, and PG4 are positioned, and the pixels arranged in the first pixel group PG1, the second pixel group PG2, and the fourth pixel group PG4 can be driven, and the third pixel group PG3 may not be driven. However, the present disclosure is not limited thereto.

In the second unit emission region UA, positions where the ON pixels (ON R PIXEL, ON G PIXEL, and ON B PIXEL) are arranged can correspond to the portions where the first pixel group PG1 and the fourth pixel group PG4 are positioned. In the fourth unit emission region UT, positions where the ON pixels (ON R PIXEL, ON G PIXEL, and ON B PIXEL) are arranged can correspond to portions where the first pixel group PG1, the second pixel group PG2, and the fourth pixel group PG4 are positioned.

In the fourth unit emission region UT, positions where the driven pixels are arranged can correspond to the portions where the first pixel group PG1, the second pixel group PG2, and the fourth pixel group PG4 are positioned, and in the second unit emission region UA, positions where the driven pixels are arranged can correspond to the portions where the first pixel group PG1 and the fourth pixel group PG4 are positioned.

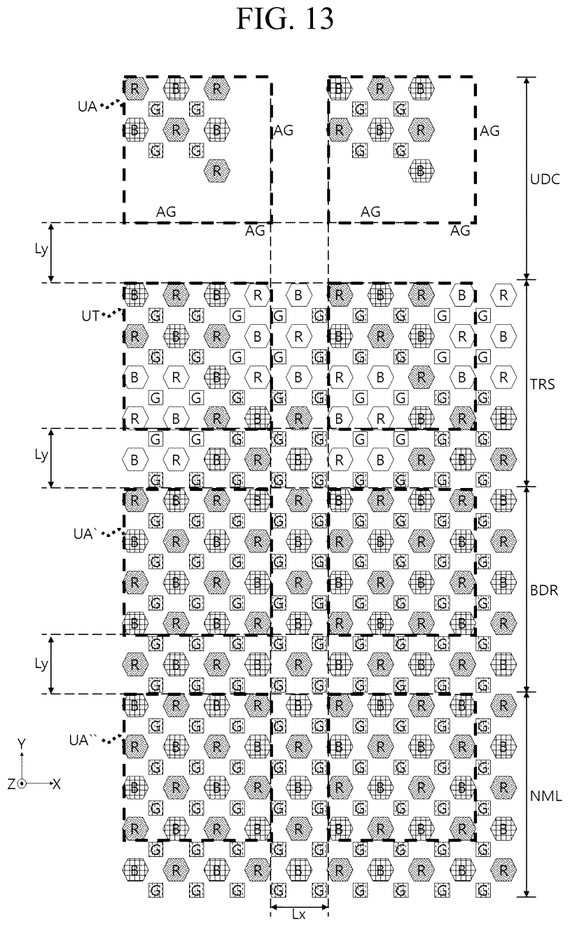

FIG. 13 is a diagram illustrating a spatial period (or arrangement relationship) of a unit emission region in a display panel according to one example embodiment of the present disclosure.

Referring to FIG. 13, the first region NML, the second region UDC, the boundary region BDR, and the transition region TRS can be arranged to extend in the first direction (e.g., the Y-axis direction) and a second direction (e.g., the X-axis direction) intersecting the first direction. In addition, the unit emission regions included in each region are not limited to the shapes illustrated in the first to third example embodiments described above and can be configured differently.

The unit emission regions of the first region NML, the second region UDC, the boundary region BDR, and the transition region TRS can be defined to have substantially the same or similar sizes.

The unit emission regions UA″, UA, UA′, and UT of the respective regions NML, UDC, BDR, and TRS can extend in multiple numbers in the first direction within each region. In this case, first-direction separation distances Ly between the first unit emission regions UA″ in the first region NML can be formed to be substantially the same or similar to each other. In the second region UDC, the first-direction separation distances Ly between the second unit emission regions UA can be formed to be substantially the same or similar to each other. In the boundary region BDR, the first-direction separation distances Ly between the third unit emission regions UA′ can be formed to be substantially the same or similar to each other. In the transition region TRS, the first-direction separation distances Ly between the fourth unit emission regions UT can be formed to be substantially the same or similar to each other.

In the first region NML, second-direction separation distances Lx between the first unit emission regions UA″ can be formed to be substantially the same or similar to each other. In the second region UDC, the second-direction separation distances Lx between the second unit emission regions UA can be formed to be substantially the same or similar to each other. In the boundary region BDR, the second-direction separation distances Lx between the third unit emission regions UA′ can be formed to be substantially the same or similar to each other. In the transition region TRS, the second-direction separation distances Lx between the fourth unit emission regions UT can be formed to be substantially the same or similar to each other.

Referring to FIG. 13, the first-direction separation distances Ly between the first unit emission region UA″ and the third unit emission region UA′ at the boundary between the first region NML and the boundary region BDR can all be formed to be substantially the same or similar. The first-direction separation distances Ly between the third unit emission region UA′ and the fourth unit emission region UT at the boundary between the boundary region BDR and the transition region TRS can all be formed to be substantially the same or similar. The first-direction separation distances Ly between the fourth unit emission region UT and the second unit emission region UA at the boundary between the transition region TRS and the second region UDC can all be formed to be substantially the same or similar. The above-described example embodiments all pertain to cases where the boundary region BDR is positioned at one side of the first region NML in the first direction, the transition region TRS is positioned at one side of the boundary region BDR in the first direction, or the second region UDC is positioned at one side of the transition region TRS in the first direction, but the present disclosure is not limited thereto. For example, the boundary region BDR is positioned at upper side of the first region NML in the first direction, the transition region TRS is positioned at upper side of the boundary region BDR in the first direction, and the second region UDC is positioned at upper side of the transition region TRS in the first direction. For example, when the transition region TRS is positioned at one side of the boundary region BDR in the second direction, the second-direction separation distances between the third unit emission region UA′ and the fourth unit emission region UT at the boundary between the boundary region BDR and the transition region TRS can all be formed to be substantially the same.

Accordingly, the emission spatial periods at the boundaries of the respective regions can be set to be substantially the same or similar based on the aforementioned spatial period, and the sense of heterogeneity caused by the luminance difference between the respective regions at the boundaries can be alleviated or prevented.

FIG. 14 is a plan view illustrating a display panel according to a fourth example embodiment of the present disclosure. FIG. 15 is a diagram illustrating a graph that describes the maximum value among the luminance values of respective pixels with reference to the display panel according to the fourth example embodiment of the present disclosure. In the table of FIG. 15, numbers outside the parentheses indicate the luminance of the pixel group PG and numbers inside the parentheses indicate the luminance contribution ratio (%) of the pixel group PG to which an area ratio is applied.

Referring to FIGS. 14 and 15, the fourth example embodiment can be substantially the same as the first example embodiment in terms of the number of pixels arranged per unit area, the number of driven pixels per unit area, the pixel density, and the like, but the present disclosure is not necessarily limited thereto. The fourth example embodiment differs from the first example embodiment in the size and/or shape of the first to fourth unit emission regions UA″, UA, UA′, and UT. The size and/or shape of the unit emission region is merely example, and the scope of the present claims is not limited to the illustrated shape and/or size of the unit emission region.

In addition, as described above, when divided into the pixel groups PG1, PG2, PG3, and PG4, their sizes or areas can be formed to be the same, and thus, a pixel that is not included in any of the pixel groups can exist. For example, the first region NML can include the first unit emission region UA″. The first unit emission region UA″ can include the first to fourth pixel groups PG1, PG2, PG3, and PG4, each having one ON R pixel, one ON B pixel, and one ON G pixel. An ON R pixel surrounded by them may not be included in any of the pixel groups. Since the ON R pixel is a pixel left over in the process of dividing into the pixel groups having the same area, it can be derived to be included in all of the pixel groups. For example, the first unit emission region UA″ can include the first to fourth pixel groups PG1, PG2, PG3, and PG4, each having two ON R pixels, one ON B pixel, and one ON G pixel. The remaining pixel may not be included in any of the pixel groups, or can be commonly included in all of the pixel groups.

The following description of the maximum luminance and the like assumes that, in each unit emission region, the effects of constructive or destructive interference caused by light emitted from each pixel group PG are negligible, and the respective unit emission regions emit light at the same luminance (e.g., 400 (relative value, arbitrary unit, A.U.)). In addition, as illustrated in the FIG. 15, one pixel group PG includes only one pixel, but this is merely example and is not limited thereto, and it can include a plurality of pixels.

The first pixel group PG1 positioned in the second region UDC can emit light at a luminance of 400. In this case, the luminance contribution ratio of the first pixel group PG1 is 400×¼=100(%). The maximum value among the luminance values of the respective pixels arranged in the second region UDC is 400.

The pixels arranged and driven in the transition region TRS can all emit light at the same luminance. As the pixels driven in the transition region TRS all emit light at the same luminance, power consumption can be reduced and a life cycle can be improved. In one example embodiment, the pixels can emit light at different luminances. The first pixel group PG1 positioned in the transition region TRS can emit light at a luminance of 200 and the fourth pixel group PG4 can emit light at a luminance of 200. In this case, the luminance contribution ratio of each of the first pixel group PG1 and the fourth pixel group PG4 is 200×¼=50(%). The maximum value among the luminance values of the respective pixels arranged in the second region UDC is 200.

The boundary region BDR can include a first boundary region BDR1 including a third-first unit emission region UA′ and a second boundary region BDR2 including a third-second unit emission region UA′. However, the boundary region BDR is not limited thereto and can include a plurality of n^{th} boundary regions BDRn including a plurality of unit emission regions. The third-second unit emission region UA′ can be positioned relatively closer to the first region NML.

The maximum value among the luminance values of the respective pixels arranged in the plurality of boundary regions BDR or the unit emission regions UA′ can vary gradually and/or continuously. For example, the maximum value can gradually and/or continuously decrease toward the first region NML. However, the present disclosure is not limited thereto.

For example, the difference (e.g., 160−100=60) between the maximum value (e.g., 160) among the luminance values of the respective pixels arranged in the third-first unit emission region UA′ and the maximum value (e.g., 100) among the luminance values of the respective pixels arranged in the first unit emission region UA″ can be greater than the difference (e.g., 120−100=20) between the maximum value (e.g., 120) among the luminance values of the respective pixels arranged in the third-second unit emission region UA′ and the maximum value (e.g., 100) among the luminance values of the respective pixels arranged in the first unit emission region UA″. However, the present disclosure is not limited thereto.

The first pixel group PG1 positioned in the first boundary region BDR1 can emit light at a luminance of 160, the second pixel group PG2 can emit light at a luminance of 40, the third pixel group PG3 can emit light at a luminance of 40, and the fourth pixel group PG4 can emit light at a luminance of 160. In this case, the luminance contribution ratio of each of the first pixel group PG1 and the fourth pixel group PG4 is 160×¼=40(%), and the luminance contribution ratio of each of the second pixel group PG2 and the third pixel group PG3 is 40×¼=10(%). The maximum value among the luminance values of the respective pixels arranged in the first boundary region BDR1 is 160.

The first pixel group PG1 positioned in the second boundary region BDR2 can emit light at a luminance of 120, the second pixel group PG2 can emit light at a luminance of 80, the third pixel group PG3 can emit light at a luminance of 80, and the fourth pixel group PG4 can emit light at a luminance of 120. In this case, the luminance contribution ratio of each of the first pixel group PG1 and the fourth pixel group PG4 is 120×¼=30(%), and the luminance contribution ratio of each of the second pixel group PG2 and the third pixel group PG3 is 80×¼=20(%). The maximum value among the luminance values of the respective pixels arranged in the second boundary region BDR2 is 120.

The first to fourth pixel groups PG1, PG2, PG3, and PG4 positioned in the first region NML can each emit light at a luminance of 100. In this case, the luminance contribution ratio of each of the first to fourth pixel groups PG1, PG2, PG3, and PG4 is 100×¼=25(%). The maximum value among the luminance values of the respective pixels arranged in the first region NML is 100.

The maximum value (e.g., 400) among the luminance values of the respective pixels arranged in the second region UDC can be greater than the maximum values (e.g., 200, 160, 120, and 100) among the luminance values of the respective pixels arranged in the first region NML, the boundary region BDR, and the transition region TRS.

The maximum value (e.g., 200) among the luminance values of the respective pixels arranged in the transition region TRS can be greater than the maximum value (e.g., 100) among the luminance values of the respective pixels arranged in the first region NML.

The maximum value (e.g., 160) among the luminance values of the respective pixels arranged in the boundary region BDR can be greater than the maximum value (e.g., 100) among the luminance values of the respective pixels arranged in the first region NML.

The maximum value (e.g., 200) among the luminance values of the respective pixels arranged in the transition region TRS can be greater than or equal to the maximum value (e.g., 160) among the luminance values of the respective pixels arranged in the boundary region BDR.

At the boundary between the boundary region BDR and the transition region TRS, there can be an inflection point V at which the luminance gradient of the pixels changes. For example, the absolute value (e.g., zero) of the average change in the luminance of the pixels in the transition region TRS can be smaller than the absolute value (e.g., a value greater than zero) of the average change in the luminance of the pixels in the boundary region BDR.

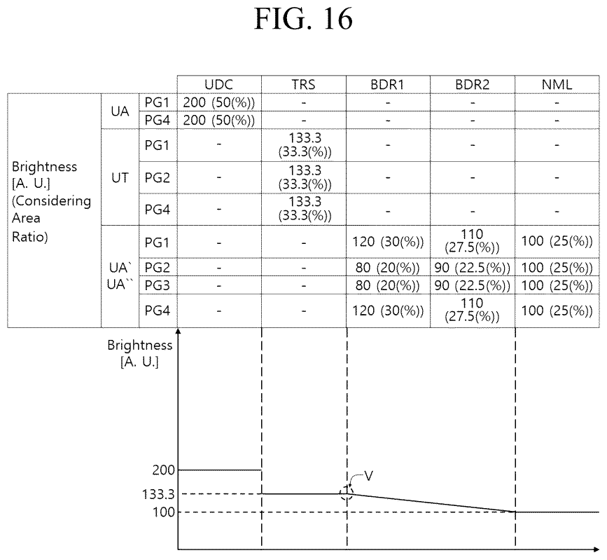

FIG. 16 is a diagram illustrating a graph that describes the maximum value among the luminance values of respective pixels in a display panel according to a fifth example embodiment of the present disclosure.

The example embodiment shown in FIG. 16 can be substantially the same as the third example embodiment in terms of the number of pixels arranged per unit area, the number of driven pixels per unit area, the pixel density, and the like. The example embodiment shown in FIG. 16 differs from the fourth example embodiment in terms of the emission luminance of each pixel group PG and the like.

Referring to FIG. 16, the first pixel group PG1 and the fourth pixel group PG4 positioned in the second region UDC can each emit light at a luminance of 200. In this case, the luminance contribution ratio of each of the first pixel group PG1 and the fourth pixel group PG4 is 200×¼=50(%). The maximum value among the luminance values of the respective pixels arranged in the second region UDC is 200.

The first pixel group PG1, the second pixel group PG2, and the fourth pixel group PG4 positioned in the transition region TRS can each emit light at a luminance of 133.3. In this case, the luminance contribution ratio of each of the first pixel group PG1, the second pixel group PG2, and the fourth pixel group PG4 is 133.3×¼=33.3(%). The maximum value among the luminance values of the respective pixels arranged in the second region UDC is 133.3.

The first pixel group PG1 positioned in the first boundary region BDR1 can emit light at a luminance of 120, the second pixel group PG2 can emit light at a luminance of 80, the third pixel group PG3 can emit light at a luminance of 80, and the fourth pixel group PG4 can emit light at a luminance of 120. In this case, the luminance contribution ratio of each of the first pixel group PG1 and the fourth pixel group PG4 is 120×¼=30(%), and the luminance contribution ratio of each of the second pixel group PG2 and the third pixel group PG3 is 80×¼=20(%). The maximum value among the luminance values of the respective pixels arranged in the first boundary region BDR1 is 120.

The first pixel group PG1 positioned in the second boundary region BDR2 can emit light at a luminance of 110, the second pixel group PG2 can emit light at a luminance of 90, the third pixel group PG3 can emit light at a luminance of 90, and the fourth pixel group PG4 can emit light at a luminance of 110. In this case, the luminance contribution ratio of each of the first pixel group PG1 and the fourth pixel group PG4 is 110×¼=27.5(%), and the luminance contribution ratio of each of the second pixel group PG2 and the third pixel group PG3 is 90×¼=22.5(%). The maximum value among the luminance values of the respective pixels arranged in the second boundary region BDR2 is 110.

The first to fourth pixel groups PG1, PG2, PG3, and PG4 positioned in the first region NML can emit light at a luminance of 100. In this case, the luminance contribution ratio of each of the first to fourth pixel groups PG1, PG2, PG3, and PG4 is 100×¼=25(%). The maximum value among the luminance values of the respective pixels arranged in the first region NML is 100.

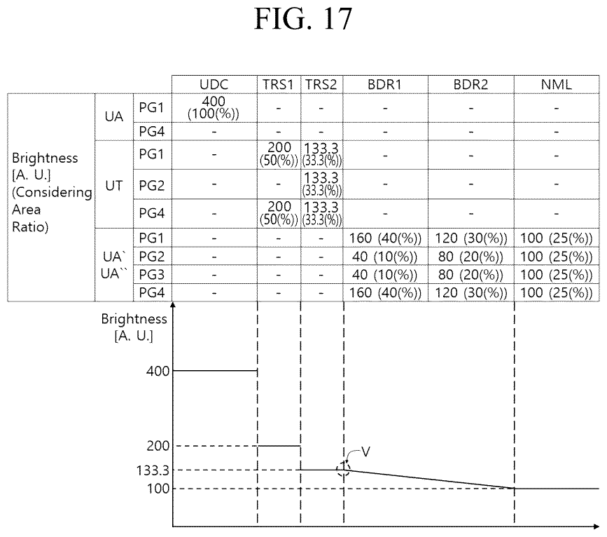

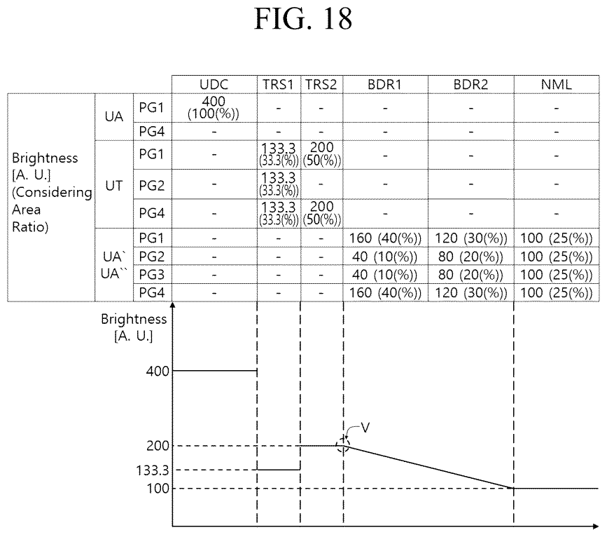

FIG. 17 is a diagram illustrating a graph that describes the maximum value among the luminance values of respective pixels in a display panel according to a sixth example embodiment of the present disclosure. FIG. 18 is a diagram illustrating a graph that describes the maximum value among the luminance values of respective pixels in a display panel according to a seventh example embodiment of the present disclosure. A detailed description of numerical values that are substantially the same as those in the above-described example embodiments will be omitted or may be briefly provided.

Referring to FIGS. 17 and 18, the transition region TRS can include a first transition region TRS1 including a fourth-first unit emission region UT and a second transition region TRS2 including a fourth-second unit emission region UT. However, the transition region TRS is not limited thereto and can include a plurality of n^{th} transition regions TRSn including a plurality of unit emission regions. The fourth-second unit emission region UT can be positioned relatively closer to the first region NML.

In the following, the plurality of transition regions TRS can be distinguished based on the maximum value among the luminance values of the pixels included in each transition region TRS. In one example embodiment, the lengths of the plurality of transition regions TRS can also be adjusted to further alleviate the visibility of the boundary.

When the transition region TRS includes the plurality of transition regions TRS1 and TRS2, the pixels arranged and driven in each of the transition regions TRS1 and TRS2 can all emit light at the same luminance. As the driven pixels in each of the transition regions TRS1 and TRS2 can all emit light at the same luminance, power consumption can be reduced and a life cycle can be improved. In one example embodiment, the pixels can emit at different luminance.

The maximum value (e.g., 200 or 133.3) among the luminance values of the respective pixels arranged in the fourth-first unit emission region UT can differ from the maximum value (e.g., 133.3 or 200) among the luminance values of the respective pixels arranged in the fourth-second unit emission region UT.

Referring to FIG. 17, the maximum value (e.g., 200) among the luminance values of the respective pixels arranged in the fourth-first unit emission region UT can be greater than the maximum value (e.g., 133.3) among the luminance values of the respective pixels arranged in the fourth-second unit emission region UT. In a case where the transition region TRS has a stepwise configuration in which the transition region TRS is divided into a plurality of transition regions TRS, the number of elements experiencing a reduction in lifespan due to high luminance emission can decrease. For example, compared to a case where the initial luminance of the first transition region TRS1 is set to 133.3, which is the same as that of the second transition region TRS2, the visibility of the boundary can be reduced when the initial luminance of the first transition region TRS1 is set to 200, which is higher than that of the second transition region TRS2. In addition, since the transition region TRS is configured as the plurality of transition regions, the likelihood of visual recognition of the boundary between the first region NML and the second region UDC can be further reduced.

Referring to FIG. 18, the maximum value (e.g., 133.3) among the luminance values of the respective pixels arranged in the fourth-first unit emission region UT can be smaller than the maximum value (e.g., 200) among the luminance values of the respective pixels arranged in the fourth-second unit emission region UT. Accordingly, the degree of element lifespan reduction of the pixels arranged in the fourth-first unit emission region UT can be reduced. For example, when the initial luminance of the first transition region TRS1 is configured to be higher than that of the second transition region TRS2, the pixels arranged in the first transition region TRS1 can experience a relatively greater degree of lifespan reduction due to degradation. To improve this, by configuring the initial luminance of the first transition region TRS1 to be lower than that of the second transition region TRS2 within a range where the boundary is not visually recognized, the degree of lifespan reduction of the pixels arranged in the first transition region TRS1 can be alleviated. In one example embodiment, while configuring the initial luminance of the first transition region TRS1 to be lower than the initial luminance of the second transition region TRS2, the length of the first transition region TRS1 in the first direction (e.g., the Y-axis direction) can be configured to be relatively small. Accordingly, it is possible to alleviate the degree of lifespan reduction of the pixels and simultaneously reduce the likelihood of visual recognition of the boundary.

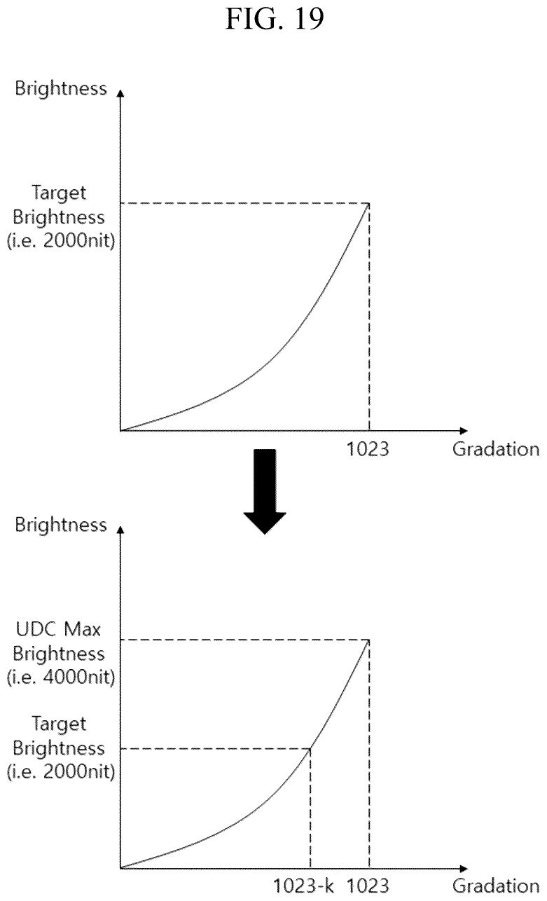

FIG. 19 is a diagram illustrating a graph that describes the problem of the reduction in the range of data voltages that can be used in a display device.

Referring to FIG. 19, since the second region UDC, in which the optical element can be positioned below the screen, includes the light transmitting portion AG due to reasons such as light reception by the optical element, the luminance of the pixels arranged in the second region UDC is inevitably adjusted to be relatively higher than that in the first region NML. Since the luminance value of the pixel can be determined by the gradation of the pixel data, a gradation value supplied to the entire screen of the display device needs to be adjusted using, as an upper limit, the gradation (or, luminance) (e.g., 4000 nits) of the pixel data arranged in the second region UDC, which is adjusted to be relatively high.

The gradation range (˜1023-k) of the data for supplying a target luminance (e.g., 2000 nits) in the first region NML is reduced by k due to the gradation of the data (e.g., 1023) for supplying a target luminance (e.g., 4000 nits) in the second region UDC, which serves as an upper limit reference, thereby determining the range of available data voltages within the reduced range.

The maximum value among the luminance values of the respective pixels arranged in the boundary region BDR can gradually and/or continuously decrease toward the first region NML from the second region UDC. Since the upper limit of the data gradation value is determined based on the second region UDC and the maximum value needs to decrease toward the first region NML, the pixels arranged in a portion of the boundary region BDR adjacent to the second region UDC are inevitably driven at high luminance. As a result, the element lifespan of the pixels arranged in the adjacent portion can be reduced.

In the display panel according to the present disclosure, the transition region TRS can be positioned between the boundary region BDR and the second region UDC, thereby reducing the degree of reduction or the amount of reduction of the element lifespan and the range of the available data voltages. In addition, as the power consumption of the display device decreases, low power driving can be enabled.

Although example embodiments of the present disclosure have been described in more detail with reference to the accompanying drawings, the present invention is not necessarily limited to these example embodiments, and can be variously modified without departing from the technical idea of the present invention.

Accordingly, the example embodiments disclosed herein are not intended to limit the technical spirit of the present invention but merely illustrate it, and the scope of the technical idea of the present invention is not limited by these example embodiments of the present disclosure.

Therefore, it should be understood that the example embodiments of the present disclosure described above are illustrative in all respects and are not limited.

The scope of protection of the present invention should be interpreted based on the claims, and all technical ideas within an equivalent scope thereof should be interpreted as being included in the scope of the present invention.

What is claimed is:

1. A display panel comprising:
a first region including a plurality of pixels having a first pixel density;
a second region including a plurality of pixels having a second pixel density that is lower than the first pixel density;
a boundary region including a plurality of pixels having a third pixel density that is higher than the second pixel density and equal to the first pixel density, the boundary region including a plurality of unit emission regions in which a maximum value among luminance values of respective pixels gradually changes; and
a transition region including a plurality of pixels having a fourth pixel density that is higher than the second pixel density and lower than the third pixel density,
wherein a boundary between the boundary region and the transition region includes an inflection point where a luminance gradient of pixels changes.

2. The display panel of claim 1, wherein in the boundary region, the maximum value among the luminance values of respective pixels gradually decreases in a direction toward the first region from the boundary region.

3. The display panel of claim 1, wherein an absolute value of an average change in luminance of the pixels in the transition region is smaller than an absolute value of an average change in the luminance of the pixels in the boundary region.

4. The display panel of claim 1, wherein a pixel density, in each of the first pixel density, the second pixel density, the third pixel density, and the fourth pixel density, is defined as the number of driven pixels per unit area.

5. The display panel of claim 1, wherein the first region includes a first unit emission region,
the second region includes a second unit emission region positioned at one side of the first unit emission region in a first direction,
the boundary region includes a third unit emission region positioned at the one side of the first unit emission region in the first direction,
the transition region includes a fourth unit emission region positioned at the one side of the first unit emission region in the first direction,
areas of the first to fourth unit emission regions are the same in size, and
a position of driven pixels in the second unit emission region corresponds to a position of driven pixels in the fourth unit emission region.

6. The display panel of claim 5, wherein the first unit emission region includes first to fourth pixel groups, each of the first to fourth pixel groups having one or more ON R pixels, one or more ON B pixels, and one or more ON G pixels.

7. The display panel of claim 6, wherein the first to fourth pixel groups are configured to emit light at a same luminance.

8. The display panel of claim 5, wherein the number of driven pixels in the fourth unit emission region is greater than the number of driven pixels in the second unit emission region and is smaller than the number of driven pixels in the third unit emission region.

9. The display panel of claim 5, wherein a maximum value among luminance values of respective pixels arranged in the fourth unit emission region is greater than or equal to a maximum value among luminance values of respective pixels arranged in the third unit emission region.

10. The display panel of claim 1, wherein the first region includes a first unit emission region,
the second region includes a second unit emission region positioned at one side of the first unit emission region in a first direction,
the boundary region includes a third unit emission region positioned at one side of the first unit emission region in the first direction,
areas of the first to third unit emission regions are the same in size,
the third unit emission region includes a third-first unit emission region and a third-second unit emission region positioned closer to the first unit emission region than the third-first unit emission region, and
a difference between a maximum value among luminance values of respective pixels arranged in the third-first unit emission region and a maximum value among luminance values of respective pixels arranged in the first unit emission region is greater than a difference between a maximum value among luminance values of respective pixels arranged in the third-second unit emission region and the maximum value among the luminance values of the respective pixels arranged in the first unit emission region.

11. The display panel of claim 1, wherein a maximum value among luminance values of the respective pixels arranged in the second region is greater than a maximum value among luminance values of the respective pixels arranged in the first region, the boundary region, and the transition region.

12. The display panel of claim 11, wherein a maximum value among luminance values of the respective pixels arranged in the transition region is greater than a maximum value among luminance values of the respective pixels arranged in the first region.

13. The display panel of claim 11, wherein a maximum value among luminance values of the respective pixels arranged in the boundary region is greater than a maximum value among luminance values of the respective pixels arranged in the first region.

14. The display panel of claim 11, wherein a maximum value among luminance values of the respective pixels arranged in the transition region is greater than or equal to a maximum value among luminance values of the respective pixels arranged in the boundary region.

15. The display panel of claim 1, wherein the transition region includes a fourth-first unit emission region and a fourth-second unit emission region positioned closer to the boundary region than the fourth-first unit emission region, and
a maximum value among luminance values of respective pixels arranged in the fourth-first unit emission region is different from a maximum value among luminance values of respective pixels arranged in the fourth-second unit emission region.

16. The display panel of claim 15, wherein the maximum value among the luminance values of the respective pixels arranged in the fourth-first unit emission region is greater than the maximum value among the luminance values of the respective pixels arranged in the fourth-second unit emission region.

17. The display panel of claim 15, wherein the maximum value among the luminance values of the respective pixels arranged in the fourth-first unit emission region is smaller than the maximum value among the luminance values of the respective pixels arranged in the fourth-second unit emission region.

18. The display panel of claim 1, wherein the boundary region is positioned between the first region and the second region, and the transition region is positioned between the boundary region and the second region.

19. A display device comprising:
the display panel according to claim 1; and
an optical element overlapping the display panel,
wherein the optical element overlaps the second region in a plane direction of the display panel.
